(19) United States
(12) Patent Application Publication
(10) Pub. No.: US 2012/0086086 A1
(43) Pub. Date: Apr. 12, 2012

(54) MEMS DEVICE AND COMPOSITE SUBSTRATE FOR AN MEMS DEVICE

(75) Inventors: Hung-Yi LIN, Yang-Mei Town (TW); Bor-Shiun LEE, Yang-Mei Town (TW); Ming-Fa CHEN, Yang-Mei Town (TW)

(73) Assignee: TOUCH MICRO-SYSTEM TECHNOLOGY CORP., Yang-Mei Town (KR)

(21) Appl. No.: 13/169,367

(22) Filed: Jun. 27, 2011

(30) Foreign Application Priority Data
Oct. 6, 2010 (TW) 099134055

(51) Int. Cl. H01L 29/84

(52) U.S. Cl. 257/415; 257/E29.324

(57) ABSTRACT

An MEMS device and a composite substrate for an MEMS device are provided. The MEMS device comprises a first silicon structure layer and a second silicon structure layer fixedly connecting to the first silicon structure layer. The first silicon structure layer has a twistable rod and a first plane. The first silicon structure layer has a first crystal direction with a miller index of <100> and a second crystal direction with a miller index of <110>. The first crystal direction and the second crystal direction are both parallel to the first plane. The rod has an axis direction, which is parallel to the first plane and intersected by the second crystal direction. In this manner, the torsional stiffness of the rod can be improved.

### CROSS-REFERENCES TO RELATED APPLICATIONS

This application claims priority to Taiwan Patent Application No. 099134055 filed on Oct. 6, 2010, the disclosure of which is incorporated by reference herein in its entirety.

### BACKGROUND OF THE INVENTION

1. Field of the Invention

The present invention relates to a micro-electromechanical system (MEMS) device, and more particularly, to an MEMS device having a twistable rod.

2. Descriptions of the Related Art

Generally, a Silicon-On-Insulator (SOI) wafer comprises two silicon substrate layers having the same crystal directions. The reasons why the two silicon substrate layers having the same crystal directions are shown as follows:

I. Generally, the semiconductor industry should comply with the SEMI specifications. The SEMI specifications define that a 200 mm wafer shall be made to have a crystal direction of (100) (i.e., the orientation of the notch axis shall be <110>±1° for 200 mm wafers). Therefore, most 200 mm wafers available in the market have a crystal direction of (100), and silicon wafers having other crystal directions must be specially ordered.

II. Most semiconductor production facilities are provided with an alignment system, and for all 200 mm wafer production systems, a notch is used as a reference for alignment. For this reason, SOI wafers produced by standard semiconductor production facilities all have the same crystal direction.

When such SOI substrate is used to fabricate a semiconductor device or an MEMS device, it is difficult to improve the electrical properties of the device and to control the etching extent due to the influence of the crystal directions.

To improve the product yield by solving the aforesaid shortcomings, a number of solutions have been proposed successively in this industry, examples of which are those disclosed in Japan Patent Publication No. JP 6151887 and U.S. Patent Publication No. 2004/0266128. According to the two patents, the two silicon substrate layers of an SOI substrate have different crystal directions, which can improve the electrical properties of the semiconductor devices and the controllability of the etching extent.

For MEMS devices, the improvement in the mechanical properties (e.g., torsional stiffness or bending stiffness) is more important. However, the disclosures of the aforesaid patents only involve the electrical properties of semiconductor devices or the control of associated processes. The aforesaid patents do not mention the related techniques in the field of MEMS devices. Consequently, it is still impossible for those of ordinary skill in the MEMS industry to improve the mechanical properties of MEMS devices by applying the existing silicon substrate manufacturing processes.

In view of this, an urgent need exists in the art to provide a solution capable of improving at least one mechanical property of modern MEMS devices on conventional silicon substrates.

### SUMMARY OF THE INVENTION

An objective of the present invention is to provide an MEMS device. The MEMS device can improve the inadequate torsional stiffness, bending stiffness or other shortcomings in terms of mechanical properties of conventional MEMS devices on the basis of conventional wafer materials and manufacturing processes. Depending on the functional requirements of different MEMS devices, silicon wafers of different crystal directions can be used to improve the mechanical properties of the MEMS devices. For example, the present invention provides an MEMS device, which comprises a twistable rod with desirable torsional stiffness.

To achieve the aforesaid objective, the MEMS device disclosed in the present invention comprises a first silicon structure layer and a second silicon structure layer. The first silicon structure layer includes a first twistable rod and a first plane. The first silicon structure layer has at least one first crystal direction and at least one second crystal direction. The at least one first crystal direction has a miller index of <100>, while the at least one second crystal direction has a miller index of <110>. The at least one first crystal direction and the at least one second crystal direction are both parallel to the first plane. The first twistable rod has a first axis direction, which is parallel to the first plane and intersected by the at least one second crystal direction. The second silicon structure layer is fixedly connected to the first silicon structure layer, and includes a reinforcing structure and a second plane which is parallel to the first plane.

Another objective of the present invention is to provide a composite substrate for an MEMS device. The composite substrate, on the basis of conventional wafer materials and manufacturing processes, uses a combination of at least two silicon wafers having different crystal directions to correspond with the mechanical property of the MEMS device to be fabricated (e.g., a tensor in the stiffness matrix).

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a perspective view of the first preferred embodiment of an MEMS device according to the present invention;

FIG. 2 is a perspective view of the first preferred embodiment of the MEMS device according to the present invention at another viewing angle;

FIG. 3A is a schematic cross-sectional view of a silicon wafer used in the first preferred embodiment;

FIG. 3B is a schematic cross-sectional view of another silicon wafer;

FIG. 4A is a schematic view illustrating the crystal directions of the first silicon substrate in the silicon wafer used in the first preferred embodiment;

FIG. 4B is a schematic view illustrating the crystal directions of the second silicon substrate in the silicon wafer used in the first preferred embodiment;

FIG. 5 is a schematic view illustrating the relationships between the stiffness and the crystal directions for a silicon substrate with a miller index of (100);

FIG. 6A is a schematic view illustrating the directions of the first silicon structure layer formed on the first silicon substrate in the first preferred embodiment;

FIG. 6B is a schematic view illustrating the directions of the second silicon structure layer formed on the second silicon substrate in the first preferred embodiment;

FIG. 7 is a perspective view of the second preferred embodiment of the MEMS device according to the present invention;

FIG. 8A is a schematic view illustrating the directions of the first silicon structure layer formed in the first silicon substrate in the second preferred embodiment;

FIG. 8B is a schematic view illustrating the directions of the second silicon structure layer formed in the second silicon substrate in the second preferred embodiment;

FIG. 9 is a schematic view illustrating the relationships between the stiffness and the crystal directions for a silicon substrate with a miller index of (110);

FIG. 10A is a schematic view illustrating the directions of the first silicon structure layer formed in the another first silicon substrate in the second preferred embodiment;

FIG. 10B is a schematic view illustrating the directions of the second silicon structure layer formed in the second silicon substrate in the second preferred embodiment; and

FIG. 11 is a schematic view illustrating the relationships between the stiffness and the crystal directions for a silicon substrate with a miller index of (111).

### DESCRIPTION OF THE PREFERRED EMBODIMENT

The present invention provides an MEMS device. A part of the components of the MEMS device are made to be twistable to accomplish a specific mechanical purpose. For instance, the MEMS device of the present invention may be applied to a micromirror device, an angular displacement transducer (e.g., a gyroscope) or a micro pump, although it is not merely limited thereto. In the following descriptions, a micromirror device will be taken as an example in all embodiments of the MEMS device of the present invention, although this is not intended to limit the scope of the present invention.

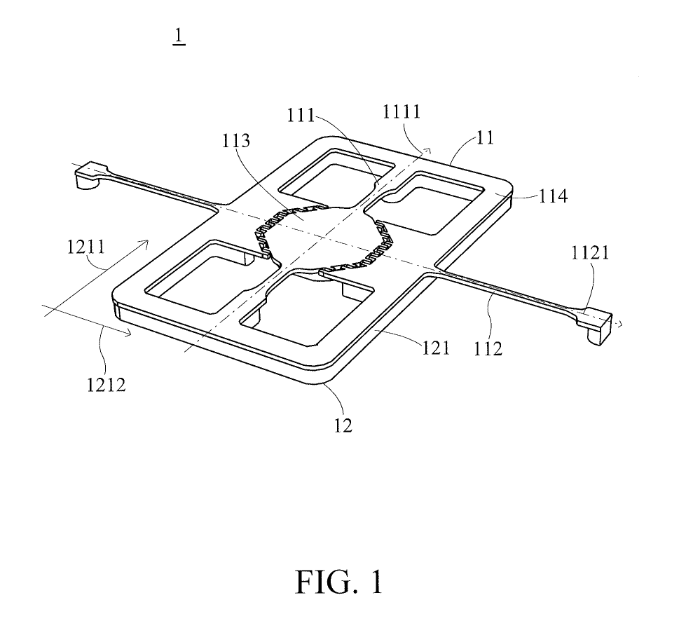

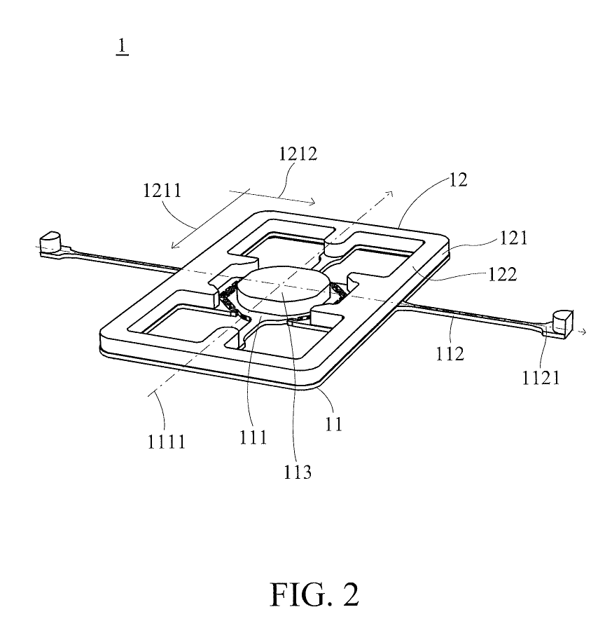

FIGS. 1 and 2 are perspective views of the first preferred embodiment of the MEMS device 1 according to the present invention. The MEMS device 1 is a biaxial micromirror device, which comprises a first silicon structure layer 11 and a second silicon structure layer 12. The first silicon structure layer 11 and the second silicon structure layer 12 are both primarily made of monocrystalline silicon, and may be doped or deposited with other materials. The second silicon layer 12 is fixedly connected to the first silicon structure layer 11. The first silicon structure layer 11 and the second silicon structure layer 12 may be fixedly connected by different ways. For example, they may be directly bonded through the Vender Walls force or connected through hydrophilic bonding, although the present invention is not merely limited thereto.

The first silicon structure layer 11 has a first rod 111 that is twistable, a second rod 112 that is twistable, a mirror structure 113 and a first plane 114. The mirror structure 113 is directly connected to the first rod 111 and indirectly connected to the second rod 112. The second rod 112 is indirectly connected to the first rod 111. The first plane 114 is perpendicular to the thickness directions of the first rod 111, the second rod 112 and the mirror structure 113.

As the first rod 111 and the second rod 112 are twistable, the first rod 111 has a first axis direction 1111, while the second rod 112 has a second axis direction 1121. The first axis direction 1111 and the second axis direction 1121 are perpendicular to each other and both parallel to the first plane 114.

When the mirror structure 113 is subjected to an external force (e.g., an electromagnetic force) and if a moment arising from the force points to the first axis direction 1111, then the mirror structure 113 will swing with respect to the first axis direction 1111 to cause torsional deformation of the first rod 111; on the other hand, if the moment arising from the force points to the second axis direction 1121, then the mirror structure 113 and the first rod 111 will both swing with respect to the second axis direction 1121 to cause torsional deformation of the second rod 112.

The second silicon structure layer 12 has a reinforcing structure 121 and a second plane 122. The reinforcing structure 121 is connected to some portions of the first silicon structure layer 11 to reinforce the mechanical strength of these portions against the deformations. In this embodiment, the portions of the first silicon structure layer 11 connected to the reinforcing structure 121 include the mirror structure 113 and the first plane 114; however, other examples of accomplishing the reinforcement may also be devised by those skilled in the art, and the further descriptions will not be described herein.

As shown in FIG. 1 and FIG. 2, the reinforcing structure 121 has a first extending direction 1211 and a second extending direction 1212 which are perpendicular to each other. The first extending direction 1211 is parallel to the first axis direction 1111 of the first rod 111, while the second extending direction 1212 is parallel to the second axis direction 1121 of the second rod 112. The second plane 122 is parallel to the first plane 114 and perpendicular to the thickness direction of the reinforcing structure 121.

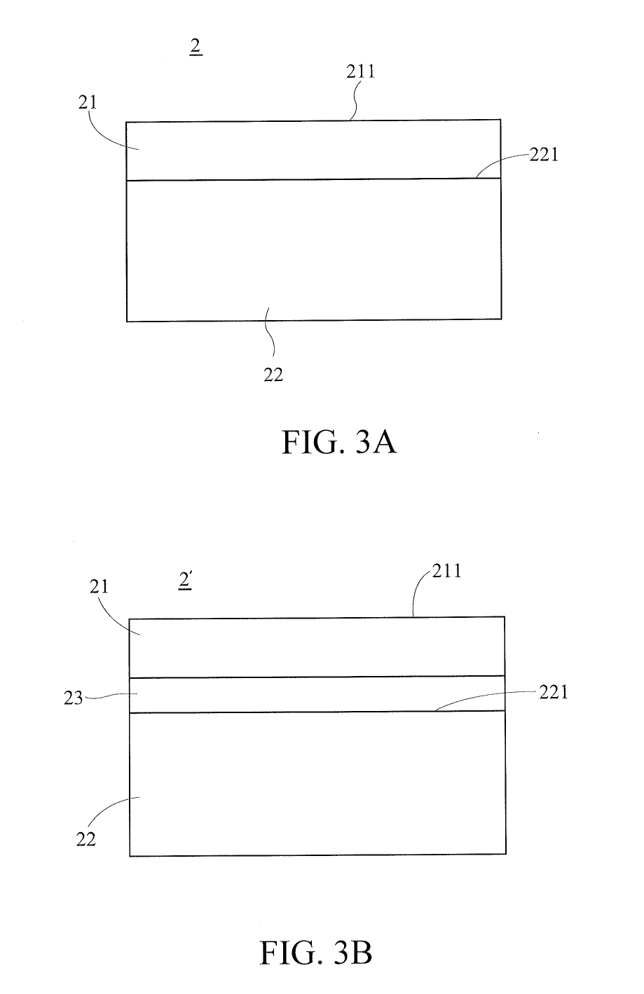

FIG. 3A illustrates a schematic cross-sectional view of a silicon wafer 2. The MEMS device 1 of this embodiment is fabricated from the silicon wafer 2. At least one characteristic of the present invention lies in that, the silicon wafer 2 for fabricating the MEMS device 1 is a composite substrate consisting of at least two silicon substrates having different crystal directions. In this embodiment, the silicon wafer 2 comprises a first silicon substrate 21 and a second silicon substrate 22 that are fixedly connected to each other. The first silicon substrate 21 and the second silicon substrate 22 may be fixedly connected by different ways. For example, they may be directly bonded through the Vender Walls force or connected through hydrophilic bonding as described above.

Alternatively, as shown in a schematic cross-sectional view of a silicon wafer 2′ in FIG. 3B, an insulation layer 23 may be selectively formed between the first silicon substrate 21 and the second silicon substrate 22. The insulation layer 23 may be made of silicon oxide. In this case, the silicon 2′ comprising the insulation layer 23 is a Silicon-On-Insulator (SOI) wafer.

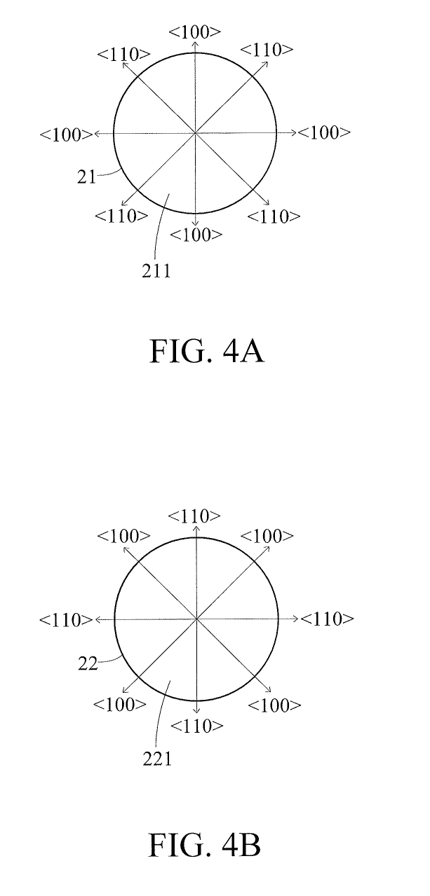

In reference to FIGS. 4A and 4B, the surface 211 of the first silicon substrate 21 and the surface 221 of the second silicon substrate 22 both have a miller index of (100). The first silicon substrate 21 further has four first crystal directions having a miller index of <100> and four second crystal directions having a miller index of <110>, all of which are parallel to the surface 211. The second silicon substrate 22 also has four third crystal directions <110> and four fourth crystal directions <100>, all of which are parallel to the surface 221. As described above, at least one characteristic of the present invention is that the first silicon substrate 21 and the second silicon substrate 22 have different crystal directions. In more detail, the first crystal directions <100> of the first silicon substrate 21 are not aligned with but have an angle with the fourth crystal directions <100> of the second silicon substrate 22; the angle is preferably 45°. Likewise, the second crystal directions <110> of the first silicon substrate 21 are not aligned with but have an angle with the third crystal directions <110> of the second silicon substrate 22; the angle is preferably 45°.

The reason why the silicon 2 for fabricating the MEMS device 1 must comprise at least two silicon substrates having different crystal directions is that the torsional stiffness and the bending stiffness of a silicon substrate are influenced by the crystal directions. Therefore, if it is desired to simultaneously improve the mechanical properties of the MEMS device 1 (e.g., improve the torsional stiffness and the bending stiffness), an appropriate matching between the crystal directions of the aforesaid silicon substrates must be made depending on the mechanical properties of different MEMS devices.

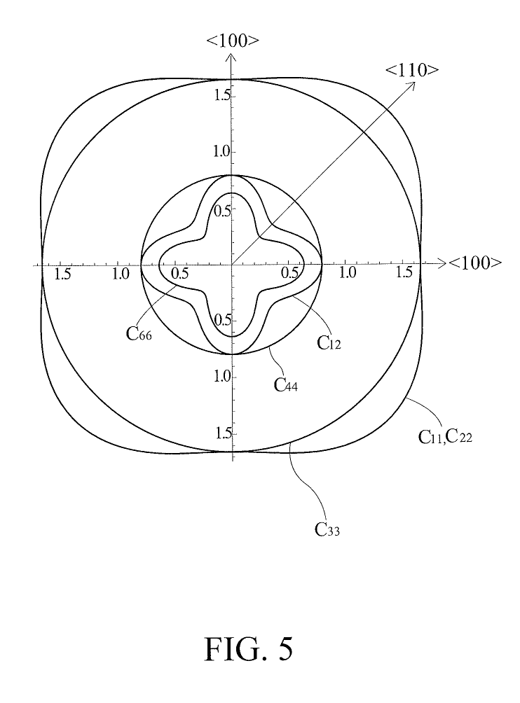

In the first preferred embodiment of the invention, the surface of the first silicon substrate 21 and that of the second silicon substrate 22 both have a miller index of (100), and a schematic view illustrating the relationships between the crystal directions and the stiffness for such silicon substrates is shown in FIG. 5 in the form of polar coordinates. In FIG. 5, C₁₂, C₂₂, C₃₃, C₄₄, C₆₆ represent tensors in a stiffness matrix, while the tensor C₆₆ is related to the torsional stiffness of the first silicon substrate 21 and the second silicon substrate 22. As shown in FIG. 5, the tensor C₆₆ has a maximum value in the crystal directions <100> and a minimum value in the crystal directions <110>. Because the bending stiffness is inversely proportional to the torsional stiffness, the bending stiffness has a maximum value in the crystal directions <110> and a minimum value in the crystal directions <100>.

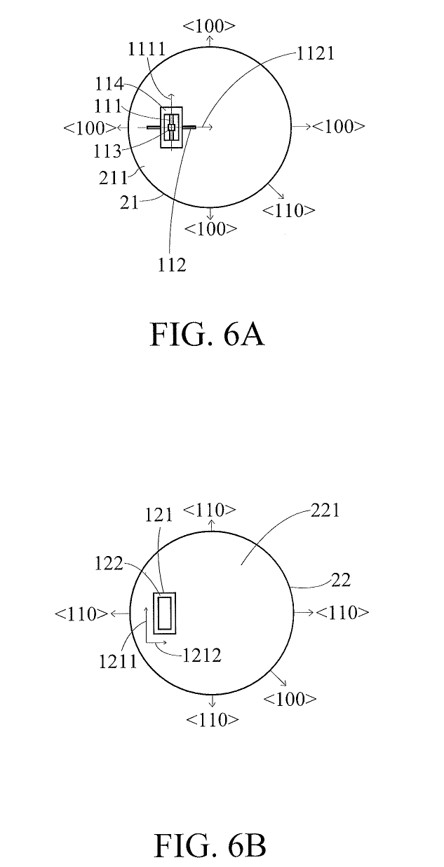

FIGS. 6A and 6B are schematic views illustrating the directions of the first silicon structure layer 11 and the second silicon structure layer 12 formed on the first silicon substrate 21 and the second silicon substrate 22 in the MEMS device 1, respectively.

As shown in FIG. 6A, in this embodiment, the first silicon structure layer 11 is fabricated from the first silicon substrate 21. The first plane 114 of the first silicon structure layer 11 is coplanar or parallel with the surface 211 of the first silicon substrate 21, and therefore, the first plane 114 has the same miller index (100) as the surface 211. Additionally, the crystal directions of the first silicon structure layer 11 are consistent with those of the first silicon substrate 21. Therefore, the first silicon structure 11 has four first crystal directions having a miller index of <100> and four second crystal directions having a miller index of <110>, all of which are parallel to the first plane 114 as shown.

The first axis direction 1111 of the first rod 111 is parallel to one first crystal direction <100> and intersected by one second crystal direction <110>. The second axis direction 1121 of the second rod 112 is parallel to another first crystal direction <100> and intersected by another second crystal direction <110>. In the above descriptions, “intersected” may also be termed as “non-parallel,” which means that the first axis direction 1111 and the second crystal direction <110> have an angle therebetween, and the second axis direction 1121 and the another second crystal direction <110> have an angle therebetween. The angles can be changed by changing the angles between the crystal directions <110> of the first silicon substrate 21 and the crystal directions <110> of the second silicon substrate 22.

It can be known by referring to FIG. 5 that the torsional stiffness can be improved as long as the crystal direction is not <110>. Therefore, the first rod 111 and the second rod 112 that are parallel to the first crystal directions <100> both have desirable torsional stiffness. Due to the improvement in the torsional stiffness, the first rod 111 and the second rod 112 are able to withstand a high-frequency reciprocating twisting of a specific torsional force. It is worth noting that the first axis direction 1111 or the second axis direction 1121 is not limited to be parallel to the first crystal direction <100>. The torsional stiffness of the first rod 111 and the second rod 112 can be improved to some extent as long as the first axis direction 1111 and the second axis direction 1121 are intersected by the second crystal directions <110>.

As shown in FIG. 6B, in this embodiment, the second silicon structure layer 12 is fabricated from the second silicon substrate 22. The second plane 122 of the second silicon structure layer 12 is coplanar or parallel with the surface 221 of the second silicon substrate 22, and therefore, the second plane 122 has the same miller index of (100) as the surface 221. Additionally, the crystal directions of the second silicon structure layer 12 are consistent with those of the second silicon substrate 22. Therefore, the second silicon structure 12 has four third crystal directions having a miller index of <110> and four fourth crystal directions having a miller index of <100>, all of which are parallel to the second plane 122 as shown.

In the second silicon structure layer 12, the first extending direction 1211 of the reinforcing structure 121 is parallel to one third crystal direction <110> and intersected by one fourth crystal direction <100>. The second extending direction 1212 is parallel to another third crystal direction <110> and intersected by another fourth crystal direction <100>. As described above, “intersected” may also be termed as “non-parallel,” which means that the first extending direction 1211 and the fourth crystal direction <100> have an angle therebetween, and the second extending direction 1212 and the another fourth crystal direction <100> have an angle therebetween. The angles can be changed by changing the angles between the crystal directions <110> of the first silicon substrate 21 and the crystal directions <110> of the second silicon substrate 22.

It can be known from FIG. 5 and from the inversely proportional relationship between the torsional stiffness and the bending stiffness that the bending stiffness can be improved as long as the crystal direction is not <100>. Therefore, in this embodiment, the reinforcing structure 121 whose first extending direction 1211 and second extending direction 1212 are parallel to the third crystal directions <110> has the optimal bending stiffness. Furthermore, the first extending direction 1211 and the second extending direction 1212 are not limited to be parallel to the third crystal directions <110>. The bending stiffness of the reinforcing structure 121 can be improved to some extent as long as the first extending direction 1211 and the second extending direction 1212 are intersected by the third crystal directions <100>.

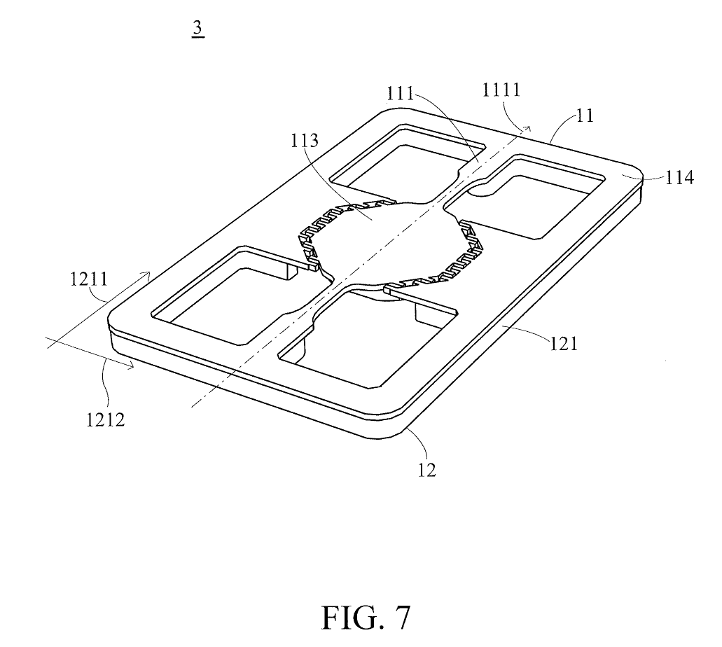

FIG. 7 illustrates a perspective view of the second preferred embodiment of the MEMS device according to the present invention. The MEMS device 3 of the second preferred embodiment differs from the MEMS device 1 of the first preferred embodiment in that the first silicon structure layer 11 of the MEMS device 3 only comprises a first twistable rod 111. In other words, the MEMS device 3 is a uniaxial micromirror device.

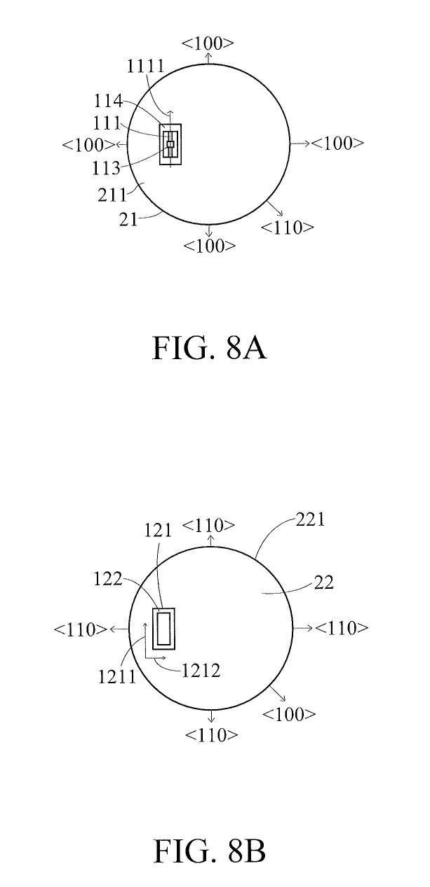

In reference to both FIGS. 8A and 8B, the schematic views illustrating the directions of the first silicon structure layer 11 and the second silicon structure layer 12 formed on the first silicon substrate 21 and the second silicon substrate 22 in the MEMS device 3 are shown therein respectively.

As described above, the surface 211 of the first silicon substrate 21 and the surface 221 of the second silicon substrate 22 both have a miller index of (100). The first silicon substrate 21 further has four first crystal directions having a miller index of <100> and four second crystal directions having a miller index of <110> (only some of them are shown), all of which are parallel to the surface 211. The second silicon substrate 22 also has four third crystal directions <110> and four fourth crystal directions <100> (only some of them are shown), all of which are parallel to the surface 221.

As shown in FIG. 8A, in this embodiment, the first axis direction 1111 of the first rod 111 is parallel to one first crystal direction <100> and intersected by one second crystal direction <110>, and therefore, the first rod 111 has desirable torsional stiffness. Additionally, the first axis direction 1111 is not limited to be parallel to the first crystal direction <100>. The torsional stiffness of the first rod 111 can be improved to some extent as long as the first axis direction 1111 is intersected by the second crystal directions <110>.

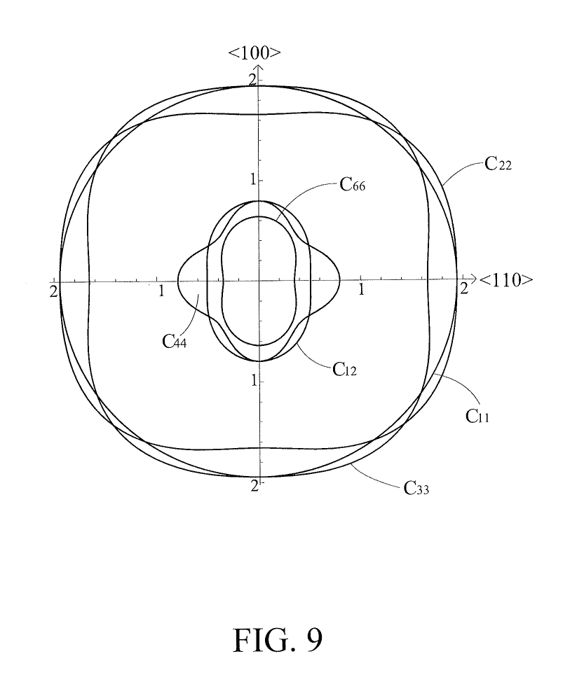

FIG. 9 illustrates a schematic view illustrating the relationships between the crystal directions and the stiffness for a silicon substrate whose surface has a miller index of (110) is shown therein in form of polar coordinates. As shown in FIG. 9, like the silicon substrate whose surface has a miller index of (100), the tensor C₆₆ that has an influence on the torsional stiffness has a maximum value in the crystal direction <100> and a minimum value in the crystal direction <110>; in other words, the bending stiffness has a minimum value in the crystal direction <100> and a maximum value in the crystal direction <110>.

Apart from being fabricated from the first silicon substrate 21 whose surface has a miller index of (100), the first silicon structure layer 11 of the MEMS device 3 may also be fabricated from a first silicon substrate 21′ whose surface has a miller index of (110). In this case, the first plane 114 of the first silicon structure layer 11 and the surface 211 both have a miller index of (110). On the other hand, the second silicon structure layer 12 can still be fabricated from the second silicon substrate 22 whose surface 221 has a miller index of (100). This example will be described in the following.

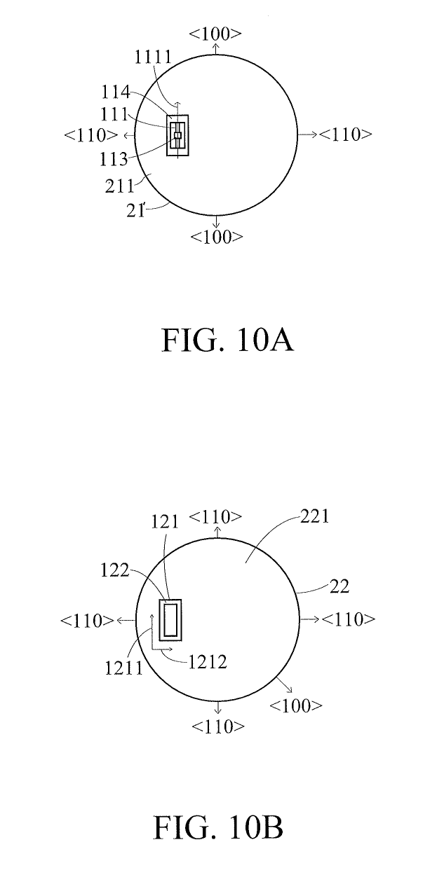

In reference to both FIGS. 10A and 10B, schematic views illustrating the directions of the first silicon structure layer 11 and the second silicon structure layer 12 formed on the first silicon substrate 21′ and the second silicon substrate 22 in the MEMS device 3 are shown therein respectively. Here, the surface 211 of the first silicon substrate 21′ has a miller index of (110).

The first silicon structure layer 11 is fabricated from the first silicon substrate 21′, and therefore, the first silicon structure layer 11 has the same crystal directions as the first silicon substrate 21′. In this case, the first silicon structure layer 11 has two first crystal directions <100> and two second crystal directions <110>. The first axis direction 1111 of the first rod 111 is parallel to the first crystal directions <100> and intersected by the second crystal directions <110>, and a desirable torsional stiffness of the first rod 111 may be achieved thereby. Additionally, even when the first axis direction 1111 is not parallel to the first crystal direction <100>, the torsional stiffness of the first rod 111 may also be improved as long as the first axis direction 1111 is intersected by the second crystal directions <110>.

Aside from the embodiments and examples described above, the second silicon structure layer of the MEMS device according to the present invention may also be fabricated from a second silicon substrate whose surface has a miller index of (110) or (111). In such a case, the miller index of the second plane of the second silicon structure layer will become (110) or (111) accordingly. To match the second silicon structure layer described above, the first silicon structure layer may be fabricated from a first silicon substrate whose surface has a miller index of (100) or (110).

As can be known from the above descriptions made with reference to FIG. 9, when the second silicon substrate whose surface has a miller index of (110) is used to fabricate the second silicon structure layer, the bending stiffness of the reinforcing structure can be improved as long as the first extending direction of the reinforcing structure is intersected by the fourth crystal directions <100>.

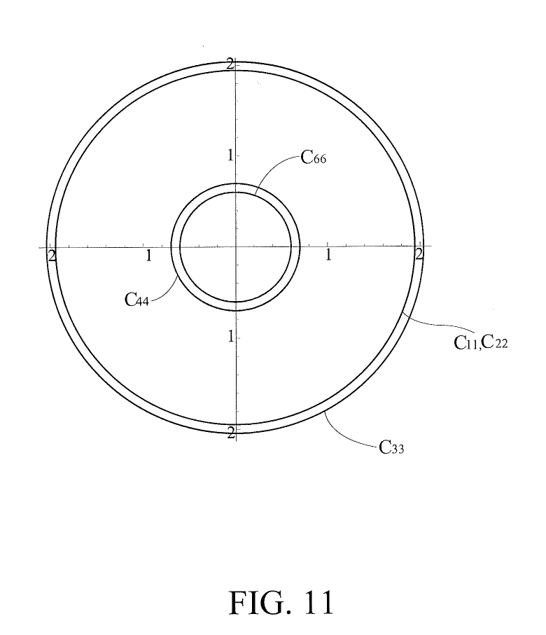

Please refer to FIG. 11, it shows the case that the second silicon substrate whose surface has a miller index of (111) is used. FIG. 11 is a schematic view illustrating the relationships between the crystal directions and the stiffness for a silicon substrate whose surface has a miller index of (111) (in form of polar coordinates). As can be seen from FIG. 11, the tensor C₆₆ which has an influence on the torsional stiffness remains constant in all crystal directions; in other words, the bending stiffness also remains constant in all crystal directions. Therefore, when the second silicon substrate whose surface has a miller index of (111) is used to fabricate the second silicon structure layer, the bending stiffness of the reinforcing structure will remain constant no matter in which crystal direction the reinforcing structure extends; in other words, the reinforcing structure has an isotropic bending stiffness.

According to the above descriptions, the MEMS device of the present invention at least has the following features:

1. When a first silicon substrate whose surface has a miller index of (100) or (110) is used to fabricate the first silicon structure layer, the torsional stiffness of the rod can be improved significantly without the need for changing the geometrical configuration thereof, as long as the first axis direction of the rod is intersected by the crystal directions <110>.
2. When a second silicon substrate whose surface has a miller index of (100) or (110) is used to fabricate the second silicon structure layer, the bending stiffness of the reinforcing structure can be improved significantly without the need for changing the geometrical configuration thereof, as long as the extending direction of the reinforcing structure is intersected by the crystal directions <100>.
3. When a second silicon substrate whose surface has a miller index of (111) is used to fabricate the second silicon structure layer, an isotropic bending stiffness will be imparted to the reinforcing structure.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. An MEMS device, comprising:
a first silicon structure layer, including a first twistable rod and a first plane, the first silicon structure layer having at least one first crystal direction and at least one second crystal direction, the at least one first crystal direction having a miller index of <100> and the at least one second crystal direction having a miller index of <110>, the first plane being parallel to the at least one first crystal direction and the at least one second crystal direction, and the first twistable rod having a first axis direction which is parallel to the first plane and intersected by the at least one second crystal direction; and
a second silicon structure layer, fixedly connected to the first silicon structure layer, and the second silicon structure layer including a second plane, which is parallel to the first plane.

2. The MEMS device as claimed in claim 1, wherein the first axis direction is parallel to the at least one first crystal direction.

3. The MEMS device as claimed in claim 1, wherein the first plane has a miller index of (100).

4. The MEMS device as claimed in claim 2, wherein the first plane has a miller index of (100).

5. The MEMS device as claimed in claim 3, wherein the first silicon structure layer further includes a second twistable rod, which is connected to the first twistable rod, and the second twistable rod has a second axis direction, which is parallel to the first plane and perpendicular to the first axis direction.

6. The MEMS device as claimed in claim 4, wherein the first silicon structure layer further includes a second twistable rod, which is connected to the first twistable rod, and the second twistable rod has a second axis direction, which is parallel to the first plane and perpendicular to the first axis direction.

7. The MEMS device as claimed in claim 1, wherein the first plane has a miller index of (110).

8. The MEMS device as claimed in claim 2, wherein the first plane has a miller index of (110).

9. The MEMS device as claimed in claim 1, wherein the second silicon structure layer further includes a reinforcing structure, the second silicon structure layer has at least one third crystal direction and at least one fourth crystal direction, the at least one third crystal direction has a miller index of <110> and the at least one fourth crystal direction has a miller index of <100>, the at least one third crystal direction and the at least one fourth crystal direction are parallel to the second plane, and the reinforcing structure has an extending direction, which is parallel to the first axis direction and intersected by the at least one fourth crystal direction.

10. The MEMS device as claimed in claim 2, wherein the second silicon structure layer further includes a reinforcing structure, the second silicon structure layer has at least one third crystal direction and at least one fourth crystal direction, the at least one third crystal direction has a miller index of <110> and the at least one fourth crystal direction has a miller index of <100>, the at least one third crystal direction and the at least one fourth crystal direction are parallel to the second plane, and the reinforcing structure has an extending direction, which is parallel to the first axis direction and intersected by the at least one fourth crystal direction.

11. The MEMS device as claimed in claim 9, wherein the second plane has a miller index of (100) or (110).

12. The MEMS device as claimed in claim 10, wherein the second plane has a miller index of (100) or (110).

13. The MEMS device as claimed in claim 9, wherein the extending direction is parallel to the at least one third crystal direction.

14. The MEMS device as claimed in claim 10, wherein the extending direction is parallel to the at least one third crystal direction.

15. The MEMS device as claimed in claim 1, wherein the second plane has a miller index of (111).

16. The MEMS device as claimed in claim 2, wherein the second plane has a miller index of (111).

17. The MEMS device as claimed in claim 1, wherein the first silicon structure layer further includes a mirror structure, which is directly connected to the first twistable rod.

18. The MEMS device as claimed in claim 2, wherein the first silicon structure layer further includes a mirror structure, which is directly connected to the first twistable rod.

19. The MEMS device as claimed in claim 5, wherein the first silicon structure layer further includes a mirror structure, which is directly connected to the first twistable rod and indirectly connected to the second twistable rod.

20. The MEMS device as claimed in claim 6, wherein the first silicon structure layer further includes a mirror structure, which is directly connected to the first twistable rod and indirectly connected to the second twistable rod.

21. The MEMS device as claimed in claim 5, wherein the second twistable rod is parallel to the at least one first crystal direction.

22. The MEMS device as claimed in claim 6, wherein the second twistable rod is parallel to the at least one first crystal direction.

23. A composite substrate for an MEMS device, comprising:
a first silicon substrate; and
a second silicon substrate, which is fixedly connected to the first silicon substrate, wherein a crystal direction of the first silicon substrate is different from a crystal direction of the second silicon substrate to correspond with a tensor of the MEMS device.
